(19) United States
(12) Patent Application Publication
(10) Pub. No.: US 2026/0259849 A1
(43) Pub. Date: Sep. 3, 2026

(54) METHOD FOR AUTOMATICALLY GENERATING INVERTER ID FOR MULTIPLE INTERFACE OPERATION AND TERMINAL DEVICE FOR DISTRIBUTED RESOURCE USING THE SAME

(71) Applicant: KOREA ELECTRIC POWER CORPORATION, Naju-si (KR)

(72) Inventors: Yoo-Jin KWON, Daejeon (KR); No-Gil MYOUNG, Daejeon (KR); Hee-Woon KANG, Daejeon (KR); Jong-Min JO, Daejeon (KR)

(21) Appl. No.: 18/715,412

(22) PCT Filed: Apr. 30, 2024
(86) PCT No.: PCT/KR2024/005885

§ 371 Date: May 31, 2024

(30) Foreign Application Priority Data
Nov. 9, 2023 (KR) 10- 2023-0154560

(51) Int. Cl. G06F 13/42; H02J 3/38; H02J 13/18

(52) U.S. Cl. CPC G06F 13/4282; H02J 3/38; H02J 13/18; G06F 2213/0002

(57) ABSTRACT

An automatic inverter ID generation method for multi-interface operation is provided. The method includes receiving a response packet from each inverter in response to a request packet transmitted to request data measurement for all inverters, determining whether a collision state with the same inverter ID through multiple interfaces is detected upon receiving the response packet, and generating, upon detecting the collision state with the same inverter ID, a new inverter ID by collecting and distinguishing channel signals based on the physical communication connections and assigning inverter group information for each channel signal to the inverter ID.

### TECHNICAL FIELD

### Technical Field

The present invention relates to an automatic inverter ID generation method for multi-interface operation and a distributed power terminal device using the same, and more particularly, to an automatic inverter ID generation method for multi-interface operation and a distributed power terminal device using the same that are capable of automatically generating inverter IDs for multi-interface operation without collision of duplicate inverter Ids after verifying the validity of collected inverter Ids from smart inverters for performing DPI-based packet filtering in the distributed power terminal device.

Furthermore, the present invention claims the benefits of Korean Patent Application No. 10-2023-0154560 filed on Nov. 9, 2023, and the entire contents thereof are incorporated herein by reference.

### Background Art

Inverters are power conversion devices that convert direct current electricity generated by renewable energy sources into alternating current electricity, commonly referred to as “grid-connected inverter.” This means that the inverter has grid connection functionality added to the power conversion process, ensuring compliance with the grid code standards of all countries that utilize alternating current grid systems.

Distributed power inverters can be defined as power conversion devices that transform the maximum direct current power generated by renewable energy sources such as solar panels into alternating current power and deliver it to the power grid.

Power systems typically maintain stable voltage and frequency, but abnormal situations (e.g., sudden load surges, power supply drops), outages, or accident can cause voltage and frequency to deviate from normal ranges. In such scenarios, distributed power inverters must shut down within a specified time frame. Distributed power inverters must also have the ability to detect and disconnect from the grid upon encountering islanding, which is a phenomenon where an outage leads to the inverter supplying power to the grid independently.

Distributed power inverters must additionally possess the capability to generate reactive power as instructed by the utility company based on grid conditions and limit the total harmonic distortion of the output current to below 5% during grid-connected operation, Additionally, distributed power inverters provide the capability to notify power generation operator of renewable energy generation status, allowing for real-time monitoring anytime.

FIG. 1 is a diagram illustrating a central inverter and a string inverter. As shown in FIG. 1, inverters can be categorized into central (centralized) and string (distributed) inverters based on their internal structure. Firstly, central inverters have the advantage of a relatively simple structure with only one maximum power point tracking (MPPT) function, and they are typically used in megawatt-scale applications. Next, string inverters can be seen as simply a downsized version of central inverters. For example, a 1 MW central inverter can be replaced by ten 100 kW inverters, and in this case, the number of MPPTs increases as much as the number of string inverters used, which has the effect of increasing power generation, reducing internal power consumption, and having greater resilience to changes in the field environmental conditions. As a result, most inverters used in small-scale residential and commercial systems with capacities below 500 kWp are string inverters.

However, for string inverters, the interface of the existing low-voltage distributed power terminal unit (DER-LV-FRTU), typically installed at the interconnection point with distribution systems of less than 500 kWp (low voltage), needs to be modified to facilitate communication-based output control and monitoring. In other words, it is not easy for low-voltage distributed power terminal units to accommodate multiple string inverters, ranging from a minimum of two to potentially dozens, installed at a single site, through a single RS-485 interface. Therefore, low-voltage distributed power terminal units require multiple communication interfaces internally, and recent requirements have changed to accommodate the provision of multiple interfaces.

Meanwhile, existing firewall devices or web application firewall (WAF) devices provide deep packet inspection (DPI) functionality for power control protocols commonly used in power networks, such as Modbus and distributed network protocol (DNP).

In recent renewable energy plants utilizing multiple string inverters, the increasing number of string inverters connected may lead to conflicts or duplication of inverter IDs, thereby imposing constraints on the application of DPI algorithms for packet filtering, even though commercial products perform DPI-based packet filtering algorithm properly when each inverter has a unique and non-duplicated ID.

For this reason, low-voltage distributed power terminal units require multiple communication interfaces to manage multiple string inverters as output control resources. However, each of these communication interfaces assigns inverter IDs for each power generation site, leading to potential conflicts or duplications of IDs during the aggregation process within the low-voltage distributed power terminal unit.

### DISCLOSURE

### Technical Problem

The present invention aims to provide an automatic inverter ID generation method for multi-interface operation and a distributed power terminal device using the same that are capable of automatically generating inverter IDs for multi-interface operation without collision of duplicate inverter IDs after verifying the validity of collected inverter IDs from smart inverters for performing DPI-based packet filtering in the distributed power terminal device.

### Technical Solution

According to an embodiment of the present invention, an automatic inverter ID generation method for multi-interface operation may include receiving a response packet from each inverter in response to a request packet transmitted to request data measurement for all inverters, determining whether a collision state with the same inverter ID through multiple interfaces is detected upon receiving the response packet, and generating, upon detecting the collision state with the same inverter ID, a new inverter ID by collecting and distinguishing channel signals based on the physical communication connections and assigning inverter group information for each channel signal to the inverter ID.

The channel signals are channel signals per RS485 port and may be collected by confirming an indication signal information of the inverter communication status on a status indicator lamp of a terminal device.

The new inverter ID may be allocated as an 8-bit data value, with the first 2 bits assigned for the inverter group information as a group number and the remaining 6 bits assigned for the inverter ID.

The new inverter ID may be generated by combining the group number and the inverter ID using a SUBSTR(∥) function.

According to another embodiment, a distributed power terminal device may include at least one processor and a memory configured to store computer-readable instructions, wherein the instructions may be executed by the at least one processor for the distributed terminal device to receive a response packet from each inverter in response to a request packet transmitted to request data measurement for all inverters, determine whether a collision state with the same inverter ID through multiple interfaces is detected upon receiving the response packet, and generate, upon detecting the collision state with the same inverter ID, a new inverter ID by collecting and distinguishing channel signals based on the physical communication connections and assigning inverter group information for each channel signal to the inverter ID.

According to another embodiment, an automatic inverter ID generation method for multi-interface operation may include receiving a response packet from each inverter in response to a request packet transmitted to request data measurement for all inverters, determining whether a collision state with the same inverter ID through multiple interfaces is detected upon receiving the response packet, collecting and distinguishing, upon detecting the collision state with the same inverter ID, channel signals based on physical communication connections and performing logical operations between the channel signals and the inverter ID for conversion to a hash value through a hash function, and generating a new inverter ID by searching for a unique inverter ID in a hash table based on the hash value.

The performing of logical operations between the channel signals and the inverter ID may include replacing the channel signals with prime numbers and performing an exclusive OR (XOR) operation with the inverter ID.

The hash value may be converted into a value between 0 and 255.

According to another embodiment, a distributed power terminal device may include at least one processor and a memory configured to store computer-readable instructions, wherein the instructions may be executed by the at least one processor for the distributed terminal device to receive a response packet from each inverter in response to a request packet transmitted to request data measurement for all inverters, determine whether a collision state with the same inverter ID through multiple interfaces is detected upon receiving the response packet, and generate, upon detecting the collision state with the same inverter ID, a new inverter ID by collecting and distinguishing channel signals based on the physical communication connections and assigning inverter group information for each channel signal to the inverter ID.

### Advantageous Effects

The present invention is advantageous in terms of facilitating DPI-based packet filtering in distributed power terminal device by automatically generating inverter Ids without collisions of inverter Ids after verifying the validity of inverters IDs collected from smart inverters.

The present invention is also advantageous in terms of being implemented efficiently and lightweight within a low-specification processor in consideration of the system specifications of the low-voltage distributed power terminal unit (DER-LV-FRTU).

The present invention is also advantageous in terms of facilitating packet correlation analysis as the core process in the DPI algorithm without inverter ID information conflicts by initially verifying the validity of inverter ID information of multiple interfaces from smart inverters configured in multiple strings and automatically mapping this information.

### DESCRIPTION OF DRAWINGS

FIG. 1 is a diagram illustrating a central inverter and a string inverter.

FIG. 2 is a diagram illustrating a distributed power terminal device according to an embodiment of the present invention;

FIG. 3 is a diagram illustrating the multi-interface structure of a distributed power terminal device in FIG. 2;

FIG. 4 is a flowchart illustrating the process of Deep Packet Inspection (DPI)-based packet filtering through automatic inverter ID generation according to an embodiment of the present invention;

FIG. 5 is a flowchart illustrating an automatic inverter ID generation method for multi-interface operation according to an embodiment of the present invention;

FIG. 6 is a diagram illustrating the front view of a distributed power terminal device;

FIG. 7 is a diagram illustrating an inverter ID incorporating the inverter group number in FIG. 5;

FIG. 8 is a flowchart illustrating automatic inverter ID generation method for multi-interface operation according to another embodiment of the present invention; and

FIG. 9 is a diagram illustrating the resolution of hash collisions using a hash table in FIG. 8.

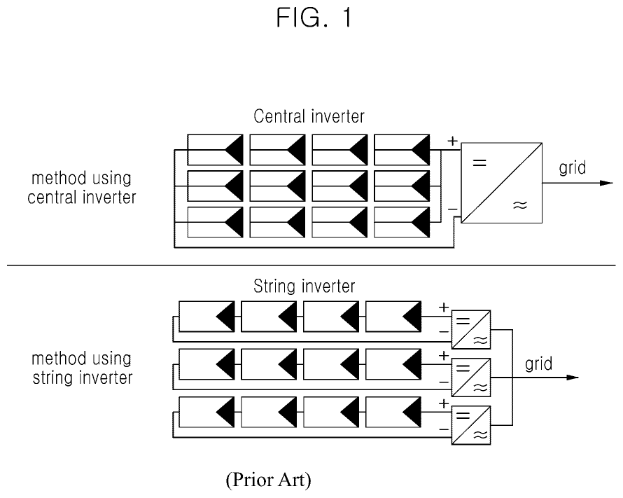

### MODE FOR INVENTION

Hereinafter, preferred embodiments of the present invention are described with reference to accompanying drawings. However, detailed descriptions of well-known functions or configurations will be omitted to avoid obscuring the subject matter of the present invention. It should be noted that the same reference numerals refer to the same components throughout the drawings.

The terms and words used in the following specification and claims should be interpreted not in a limited sense to their usual or dictionary meanings but in meanings and concepts that conform to the technical ideas of the present invention, based on the principle that the inventor can appropriately define the terms to best describe their invention.

Therefore, the embodiments described in this specification and configurations depicted in the drawings represent only the preferred embodiments of the present invention and do not fully embody all the technical ideas of the present invention, so it should be understood at the time of this application that there may be various equivalent elements and alternative embodiments that can replace them.

In the attached drawings, certain components may be exaggerated, omitted, or depicted schematically, and the sizes of individual components may not be proportional to their actual sizes. The present invention is not limited by the relative sizes or spacing shown in the attached drawings.

Also, when a part is said to “comprise” a certain component, this means that other components may be further included instead of excluding other components unless specifically stated otherwise. Additionally, when one part is “connected” to another part, it includes not only being “directly connected” but also being “electrically connected” through intermediate components.

As used herein, the singular forms are intended to include the plural forms as well, unless the context clearly indicates otherwise. The terms “comprising” or “having” indicate the presence of the features, numbers, steps, operations, components, parts, or combinations thereof as listed in the specification, without excluding the presence or possibility of one or more other features, numbers, steps, operations, components, parts, or combinations thereof.

In addition, the term “module” used in the specification means a software or hardware component such as a Field Programmable Gate Array (FPGA) or Application Specific Integrated Circuit (ASIC), which performs certain tasks. However, the term “module” is not limited to software or hardware. A “module” may be configured to reside on addressable storage media and may be configured to execute one or more processors. Thus, a module may include, by way of example, components, such as software components, object-oriented software components, class components and task components, processes, functions, attributes, procedures, subroutines, segments of program code, drivers, firmware, microcode, circuitry, data, databases, data structures, tables, arrays, and variables. The functionalities of the components and modules may be combined into fewer components and modules or further separated into more components and modules.

The embodiments of the present invention will be described in detail hereinafter with reference to the accompanying drawings to facilitate implementation by those skilled in the art within the relevant technical field. However, the present invention can be embodied in various forms, and is not limited to the embodiments described herein. In order to clearly describe the present invention, parts irrelevant to the description may be omitted in the drawings, and similar reference numerals may be used for similar components throughout the specification.

Hereinafter, preferred embodiments of the present invention are described with reference to the accompanying drawings.

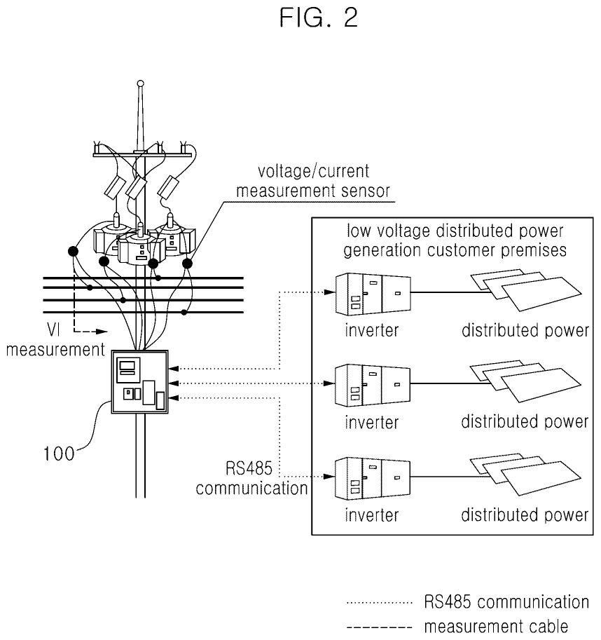

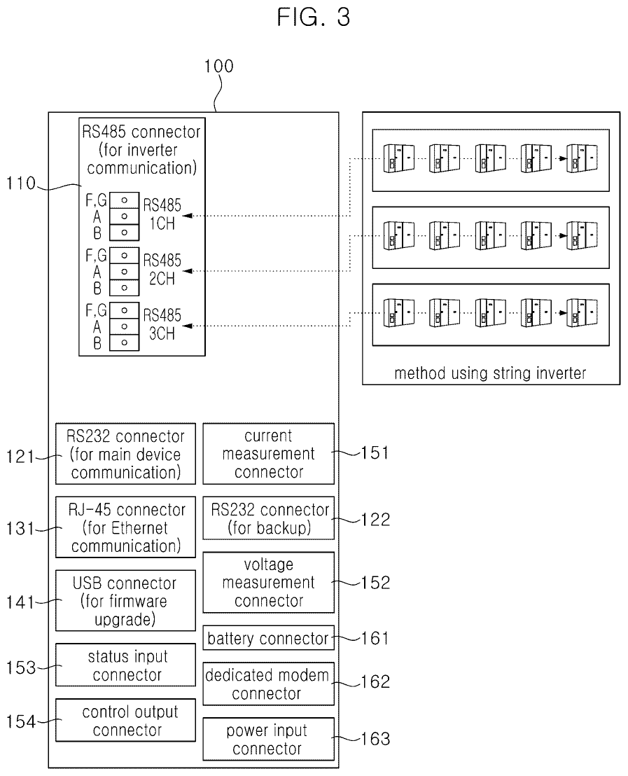

FIG. 2 is a diagram illustrating a distributed power terminal device according to an embodiment of the present invention, and FIG. 3 is a diagram illustrating the multi-interface structure of a distributed power terminal device in FIG. 2.

As shown in FIGS. 2 and 3, the distributed power terminal device 100 according to an embodiment of the present invention, installed at the interconnection point with low-voltage distribution systems of less than 500 kWp for communication with string inverters for output control and monitoring, expands physical ports to accommodate increasing numbers of string inverters and provides an RS485 multi-interface environment.

The distributed power terminal device 100 includes an RS485 connector 110 for multiple interfaces for communication with string inverters. The RS485 connector 110 is composed of three channels of serial ports for communication with multiple inverters.

In addition, the distributed power terminal device 100 includes RS232 connectors 121 and 122 for main device communication and backup, an RJ-45 connector 131 for Ethernet communication, a USB connector 141 for firmware upgrades, a current measurement connector 151 for electrical status verification, a voltage measurement connector 152, a status input connector 153, a control output connector 154, a battery connector 161 for external device connection, a dedicated modem connector 162, and a power input connector 163.

The distributed power terminal device 100 is connected to inverters from different renewable energy operators through the RS485 connector 110. In this case, the distributed power terminal device 100 connects to the serial port using the inverter ID numbers ranging from 01 to 99, designated for string inverters within the power generation site. Since inverter ID numbers are sequentially assigned and preset, they cannot be arbitrarily changed at the level of the distributed power terminal device 100 even in the event of conflicts between power generation operators. Due to the fixed settings of inverter ID numbers established during the installation phase, even if conflicts arise after on-site construction is completed, changing the inverter IDs arbitrarily without the consent of the power generation operator is difficult, and inspecting all communication specifications within the inverter device makes it impractical to change the IDs in practice.

Therefore, the distributed power terminal device 100 adjusts the numbers between conflicting inverter IDs to distinguish each inverter for output control and on-site status monitoring, and performs a bulk conversion mapping of the inverter IDs to be used in internal operations after distinguishing the physical communication connections.

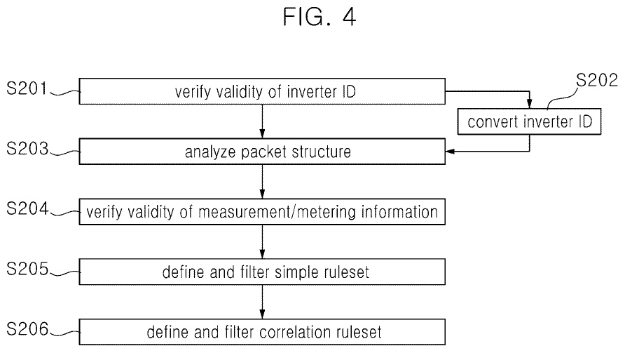

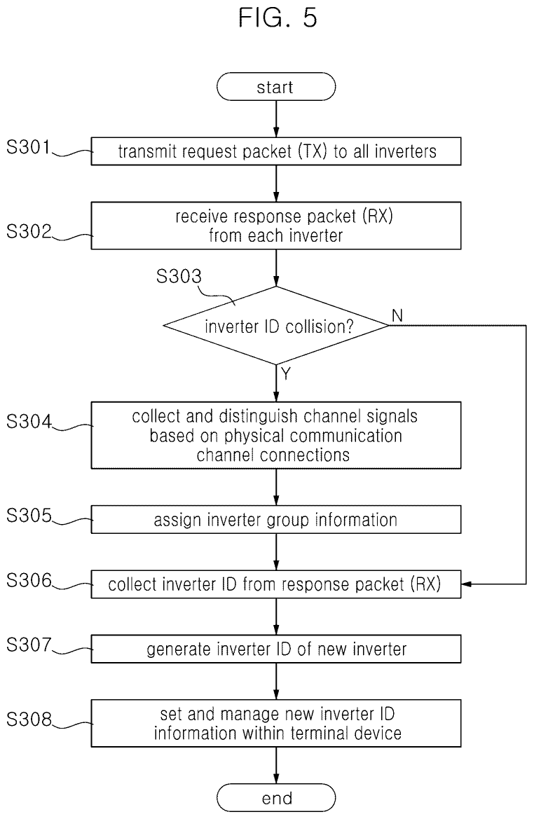

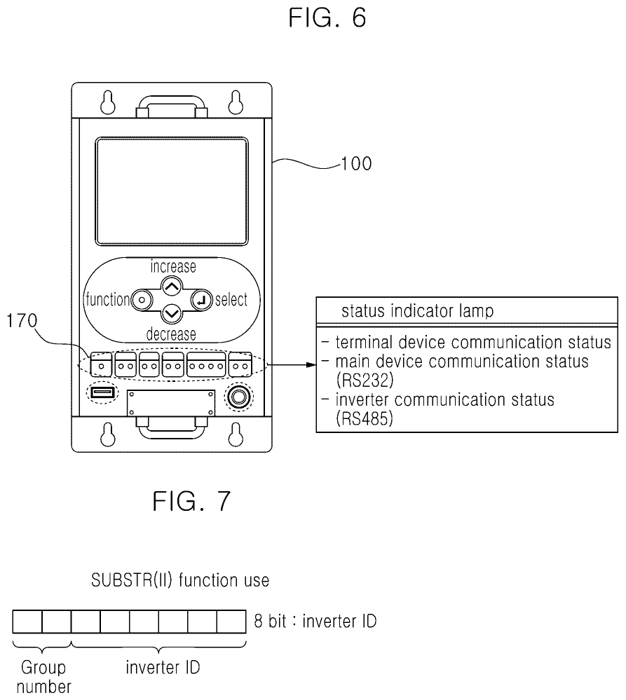

A detailed description thereof is provided with reference to FIGS. 4 to 7. FIG. 4 is a flowchart illustrating the process of DPI-based packet filtering through automatic inverter ID generation according to an embodiment of the present invention, FIG. 5 is a flowchart illustrating an automatic inverter ID generation method for multi-interface operation according to an embodiment of the present invention, FIG. 6 is a diagram illustrating the front view of a distributed power terminal device, and FIG. 7 is a diagram illustrating an inverter ID incorporating the inverter group number in FIG. 5.

The distributed power terminal device 100 includes at least one processor and memory for storing computer-readable instructions, and the computer-readable instructions stored in the memory are executed by the at least one processor to carry out the method for automatically generating inverter IDs for multi-interface operation according to embodiments of the present invention.

As shown in FIG. 4, the distributed power terminal device 100 performs deep packet inspection (DPI)-based packet filtering analysis for packets incoming to the utility company control network because the compatibility and reliability of inverter IDs from customer equipment (renewable energy generation operator's equipment) cannot be guaranteed.

Firstly, the distributed power terminal device 100 performs inverter ID validity verification at step S201 to determine whether conflicting inverter IDs occur to distinguish device information and measured values of each inverter for on-site status monitoring.

When conflicting inverter IDs occur, the distributed power terminal device 100 proceeds with signal processing differentiation based on physical communication connections and converts the inverter IDs of the respective inverters accordingly at step S202. During this process, the distributed power terminal device 100 performs bulk conversion mapping of the inverter IDs to be used in internal operations for DPI-based packet filtering inspections.

Subsequently, the distributed power terminal device 100 performs comprehensive packet inspection functionality. That is, the distributed power terminal device 100 first analyzes the structure of each communication packet at step S203 and verify the validity of measurement/metering information at step S204. Then, the distributed power terminal device 100 performs packet filtering inspections by defining a simple ruleset at step S205 and defining a correlation ruleset between request/response packets at step S206.

Meanwhile, the distributed power terminal device 100 uses the newly converted inverter ID scheme to confirm inverter information during the DPI-based packet filtering process described with reference to FIG. 4; however, in cases where further verification is required and communication with the inverter is necessary (for example, when installing a new inverter), it is necessary to manage mapping information to ensure inverter ID consistency during conversion back to original inverter IDs and performs bulk conversion mapping of inverter IDs for internal operations. FIG. 5 illustrates the verification process of the distributed power terminal device 100 for new inverter installations.

As shown in FIG. 5, the distributed power terminal device 100 transmits request packets (TX) in batch at one-minute intervals to request data measurements from all connected inverters at step S301 and receives response packets (RX) containing sets of measured values for the power output of renewable power plants from each inverter at step S302.

Upon receiving the response packets (RX) containing the same inverter ID value through the multiple interfaces, the distributed power terminal device 100 detects the collision status of inverter IDs at step S303, gathers and differentiate channel signals based on the physical communication channel connections (i.e., RS485 port-specific channel signals) at step S304, and assigns channel signal-specific inverter group information to each existing inverter ID at step S305. Here, the RS485 port constitutes a multi-interface and may be divided into three channels as described with reference to FIG. 2.

After detecting an inverter ID collision in response packets (RX), the distributed power terminal device 100 collects channel signals from each RS485 port by checking the ‘inverter communication status (RS485)’ signal information on the status indicator lamp 170 as shown in FIG. 6.

Here, the ‘inverter communication status (RS485)’ lamp indicates the connection status and transmission/reception activity for each channel (i.e., RS485-1, RS485-2, and RS485-3) in red (on) or black (off). The number of each channel corresponds to the group information assigned to each inverter.

For example, upon detecting an inverter ID collision at step S304 with the indication by the ‘inverter communication status (RS485)’ lamp turning red (on) for the receiving packet (RX) signal channels RS485-1 and RS485-3, the distributed power terminal device 100 assigns inverter group information as group 01 and group 03 to each received packet, respectively.

Next, the distributed power terminal device 100 collects the inverter ID from the response packet (RX) at step S306, generates the inverter ID for the new inverter automatically at step S307, and sets the new inverter ID within the terminal device and manage the consistency of the inverter ID to be used in internal operations at step S308.

FIG. 7 illustrates the process of automatically generating an inverter ID by incorporating additional group information (i.e., group numbers) extracted from channel signals of multiple interfaces.

As described above, the distributed power terminal device 100 may identify and assign inverter group information without any additional electronic signal processing, utilizing the status indicator lamp signals on the front panel of the existing terminal devices for communication status indication purposes. That is, upon confirming the red (on) illumination of the receiving packet (RX) lamp for the RS485-N channel signal on the front panel of the terminal device as shown in FIG. 6, the distributed power terminal device 100 recognizes this as a valid received packet and assigns additional information in the form of ‘group N’to each of these packets.

Specifically, the inverter ID is typically assigned as an 8-bit data value. Here, the first 2 bits are newly assigned as the ‘group number’, while the remaining 6 bits are used as the existing ‘inverter ID’. For this purpose, the ‘group number’ and ‘inverter ID’ are combined using the SUBSTR(∥) function. In other words, the inverter ID is used in the form of inverter ID=group number∥inverter ID. In this case, the maximum number of inverters that can be connected as a string to each RS485 port is 64 (6 bits, 2⁶=64). However, there is a limitation that renewable energy sources newly installed as a string type exceeding the maximum number of inverters cannot be accommodated within the same RS485 serial port. However, as renewable energy operators are currently instructed to distribute and accommodate up to 99 inverters within 3 serial ports when deploying string-type inverters at installation sites, it is possible to utilize the system without exceeding the maximum inverter count per RS485 port by distributing 33 inverters to each RS485 port.

In this manner, the distributed power terminal device 100 can automatically generate an inverter ID by combining inverter group information with the existing inverter ID.

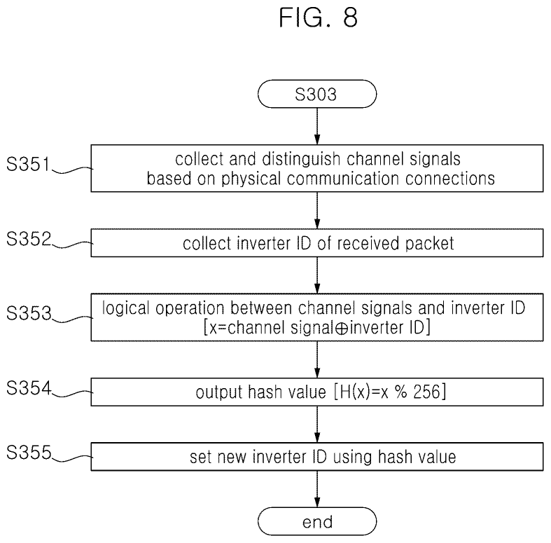

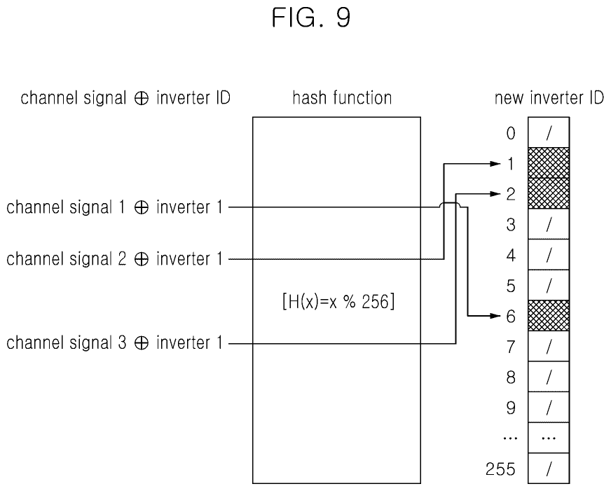

Meanwhile, a description is provided of the process for the distributed power terminal device 100 to automatically generate invert IDs according to another embodiment with reference to FIGS. 8 and 9. In this embodiment, a probing technique that utilizes a hash function to identify available inverter IDs is employed.

FIG. 8 is a flowchart illustrating automatic inverter ID generation method for multi-interface operation according to another embodiment of the present invention, and FIG. 9 is a diagram illustrating the resolution of hash collisions using a hash table in FIG. 8. In FIG. 8, step 303 is identical with that in FIG. 5, and thus the detailed explanation thereof is omitted.

In FIG. 5, a method was illustrated for automatically generating inverter IDs by combining additional group information (i.e., group numbers) extracted from channel signals of multiple interfaces.

As shown in FIGS. 8 and 9, the distributed power terminal device 100 autonomously assigns and generates inverter IDs by adapting the probing technique based on a hash function. This makes it difficult for hackers to easily match and infer inverter IDs even when they gain root access to the distributed power terminal device 100.

The measurement/metering items collected from the inverter by the distributed power terminal device 100 may include per-inverter ID, phase-specific voltage/current/active power/reactive power, three-phase average voltage/current/active power/reactive power, power factor, and frequency.

In detail, upon detecting an inverter ID collision through multiple physical interfaces at step S303, the distributed power terminal device 100 collects channel signal informations the channel signal information based on physical communication connections (i.e., channel signals per RS485 port) and the inverter ID of the received packet (RX) at step S352 and performs simple logical operations between the collected information and inverter IDs at step S353. That is, the distributed power terminal device 100 performs exclusive OR (XOR) operations between the inverter IDs and substitutes the channel signals from different physical RS485 interfaces with a very large number of prime numbers to provide unique hash values for multiple inverter IDs. This process employs the exclusive OR operation on bits, similar to cryptographic key generation, to automatically generate unique and collision-free inverter IDs for each device.

Afterwards, the distributed power terminal device 100 applies the result of the logical operations, which have been transformed into very large numbers, to a hash function to output a hash value at step S354 and sets a new inverter ID using the hash value at step S355. That is, the distributed power terminal device 100 utilizes a hash function to convert multiple inverter IDs into a hash value between 0 and 255, and then searches the hash table with 256 rows for unique inverter IDs and map and set them as a new inverter IDs as shown in FIG. 9.

In FIG. 9, the inverter ID ‘inverter 1’ is in a collision state. The distributed power terminal device 100 performs an exclusive OR operation between the channel signal information (channel signal 1, channel signal 2, and channel signal 3) and the inverter ID (inverter 1), then applies the result to a hash function to convert it into a hash value, and finally searches for a unique inverter ID within the 256-row of the hash table. Subsequently, the distributed power terminal device 100 sets the new inverter ID for the inverter 1 corresponding to channel signal 1 as ‘Inverter 6’, sets the new inverter ID for the inverter 1 corresponding to channel signal 2 as ‘inverter 1’, and sets the new inverter ID for the inverter 1 corresponding to channel signal 3 as ‘inverter 2’.

As such, embodiments of the present invention are capable of the management and operation of inverter IDs, allowing for the automatic generation of inverter IDs for multiple smart inverters without altering the device information on the inverter side, thereby facilitating the normal execution of DPI-based packet filtering processes.

Furthermore, embodiments of the present invention are capable of providing a preprocessing step for inverter ID refinement for DPI-based packet filtering algorithms, allowing the analysis of correlation between transmitted and received packets.

The method according to some embodiments may be implemented in the form of program instructions that can be executed by various computing means and recorded on computer-readable media. The computer-readable media may store program instructions, data files, data structures, or a combination thereof. The program instructions recorded on the media may be specifically designed and configured for the present invention or may be publicly known and available for use by computer software professionals. Examples of computer-readable recording media include magnetic media such as hard disks, floppy disks, and magnetic tapes, optical media such as CD-ROMs and DVDs, magneto-optical media such as floptical disks, and hardware devices specially configured to store and execute program instructions, such as ROMs, RAMs, and flash memory. Examples of program instructions include machine code generated by compilers as well as high-level language code that can be executed by a computer using interpreters and similar tools.

While the above description focuses on the novel features of the present invention applicable to various embodiments, those skilled in the art will understand that various deletions, substitutions, and modifications may be made in the form and details of the devices and methods described above without departing from the scope of the present invention. Therefore, the scope of the present invention is defined by the appended claims rather than the foregoing description. Any modifications within the scope of equivalence of the patent claims are considered to be encompassed within the scope of the invention.

1. An automatic inverter ID generation method for multi-interface operation, the method comprising:
receiving a response packet from each inverter in response to a request packet transmitted to request data measurement for all inverters;
determining whether a collision state with the same inverter ID through multiple interfaces is detected upon receiving the response packet; and
generating, upon detecting the collision state with the same inverter ID, a new inverter ID by collecting and distinguishing channel signals based on the physical communication connections and assigning inverter group information for each channel signal to the inverter ID.

2. The method of claim 1, wherein the channel signals are channel signals per RS485 port, collected by confirming an indication signal information of the inverter communication status on a status indicator lamp of a terminal device.

3. The method of claim 1, wherein the new inverter ID is allocated as an 8-bit data value, with the first 2 bits assigned for the inverter group information as a group number and the remaining 6 bits assigned for the inverter ID.

4. The method of claim 3, wherein the new inverter ID is generated by combining the group number and the inverter ID using a SUBSTR(∥) function.

5. A distributed power terminal device comprising:
at least one processor; and
a memory configured to store computer-readable instructions,
wherein the instructions are executed by the at least one processor for the distributed terminal device to receive a response packet from each inverter in response to a request packet transmitted to request data measurement for all inverters, determine whether a collision state with the same inverter ID through multiple interfaces is detected upon receiving the response packet, and generate, upon detecting the collision state with the same inverter ID, a new inverter ID by collecting and distinguishing channel signals based on the physical communication connections and assigning inverter group information for each channel signal to the inverter ID.

6. The distributed power terminal device of claim 5, wherein the channel signals are channel signals per RS485 port, collected by confirming an indication signal information of the inverter communication status on a status indicator lamp of a terminal device.

7. The distributed power terminal device of claim 5, wherein the new inverter ID is allocated as an 8-bit data value, with the first 2 bits assigned for the inverter group information as a group number and the remaining 6 bits assigned for the inverter ID.

8. The distributed power terminal device of claim 7, wherein the new inverter ID is generated by combining the group number and the inverter ID using a SUBSTR(∥) function.

9. An automatic inverter ID generation method for multi-interface operation, the method comprising:
receiving a response packet from each inverter in response to a request packet transmitted to request data measurement for all inverters;
determining whether a collision state with the same inverter ID through multiple interfaces is detected upon receiving the response packet;
collecting and distinguishing, upon detecting the collision state with the same inverter ID, channel signals based on physical communication connections and performing logical operations between the channel signals and the inverter ID for conversion to a hash value through a hash function; and
generating a new inverter ID by searching for a unique inverter ID in a hash table based on the hash value.

10. The method of claim 9, wherein the performing of logical operations between the channel signals and the inverter ID comprises replacing the channel signals with prime numbers and performing an exclusive OR (XOR) operation with the inverter ID.

11. The method of claim 9, wherein the hash value is converted into a value between 0 and 255.
